(19) United States
(12) Patent Application Publication
(10) Pub. No.: US 2026/0371001 A1
(43) Pub. Date: Nov. 19, 2026

(54) APPARATUS AND METHOD FOR DECREASING NOISE CAUSED BY ELECTROMAGNETIC INFLUENCE IN A HEADPHONE

(71) Applicant: Harman International Industries, Incorporated, Stamford, CT (US)

(72) Inventor: Linyong FAN, Shenzhen (CN)

(73) Assignee: Harman International Industries, Incorporated, Stamford, CT (US)

(21) Appl. No.: 19/730,847

(22) Filed: Jul. 3, 2026

Related U.S. Application Data
(63) Continuation of application No. PCT/CN2024/076364, filed on Feb. 6, 2024.

(51) Int. Cl. H04R 1/10; H05K 9/00

(52) U.S. Cl. CPC H04R 1/1083; H05K 9/0084

(57) ABSTRACT

An apparatus for decreasing noise caused by electromagnetic influence in a headphone includes a speaker and an electrical loop. The speaker includes a speaker coil and a speaker membrane. The electrical loop having a loop current flowing therein, arranged close to a back of the speaker. The apparatus further includes a metal plate and a magnetic plate both placed between the electrical loop and the speaker, with the metal plate located between the electrical loop and the magnetic plate. An eddy current is generated when the loop current varies in the electrical loop, and the direction of the eddy current is opposite to that of the loop current.

### CROSS-REFERENCE TO RELATED APPLICATIONS

This application is a continuation of International Application No. PCT/CN2024/076364, filed on Feb. 6, 2024. The disclosures of the above applications are incorporated herein by reference.

### FIELD

The present disclosure relates generally to noise decrease. More particularly, the present disclosure relates to an apparatus and a method for decreasing noise caused by electromagnetic influence in a headphone.

### BACKGROUND

The statements in this section merely provide background information related to the present disclosure and may not constitute prior art.

Inside a headphone, an electrical loop composed of certain components on a printed circuit board (PCB) may have electromagnetic influences on a speaker, resulting in noise. This kind of noise can be very annoying for headphone users.

At present, the noise caused by electromagnetic influences in headphones can be tested using acoustic equipment (AP), such as low-noise microphones. However, the voltage level of this type of noise cannot be tested through electrical and acoustic equipment. And when the speaker is removed from one casing and assembled into another, this noise can neither be heard nor tested by acoustic equipment.

Therefore, there is a need to provide an apparatus and method that may actively decrease the noise caused by such electromagnetic influence in the headphone.

### SUMMARY

This section provides a general summary of the disclosure and is not a comprehensive disclosure of its full scope or all of its features.

In one aspect, an apparatus for decreasing noise caused by electromagnetic influence in a headphone is provided. The apparatus comprises a speaker with a speaker coil and a speaker membrane, and an electrical loop with a loop current flowing therein. The electrical loop is arranged close to the back of the speaker in the headphone. The apparatus further comprises a metal plate and a magnetic plate both placed between the electrical loop and the speaker. The metal plate is located between the electrical loop and the magnetic plate. When the loop current varies in the electrical loop, an eddy current may be generated. The direction of the eddy current is opposite to that of the loop current.

In another aspect, a method for decreasing noise caused by electromagnetic influence in a headphone is provided. The method comprises following steps of placing a metal plate and a magnetic plate between an electrical loop and a speaker in the headphone, with the metal plate located between the electrical loop and the magnetic plate and making a loop current to flow in the electrical loop. When the loop current varies in the electrical loop, an eddy current may be generated on the metal plate, wherein the direction of the eddy current is opposite to that of the loop current.

The method further comprises a step of testing a voltage level of the noise and tuning the size and thickness of the metal plate according to the tested voltage level of the noise.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 schematically illustrates a schematic diagram of noise caused by an electromagnetic influence on a speaker from the loop current flowing in the electrical loop in a headphone;

FIG. 2A illustrates an exemplary diagram of an apparatus for decreasing noise caused by the electromagnetic influence in a headphone, according to one or more embodiments of the present disclosure;

FIG. 2B illustrates an exemplary diagram of decreasing noise caused by the electromagnetic influence in the headphone by mutual cancelling out magnetic fields in the headphone, according to one or more embodiments of the present disclosure;

FIG. 3 illustrates an exemplary flowchart of a method for decreasing noise caused by electromagnetic influence in a headphone, according to one or more embodiments of the present disclosure; and

FIG. 4 illustrates a schematic diagram of the background noise test results before and after implementing the method for decreasing noise caused by the electromagnetic influence in the headphone, according to one or more embodiments of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The detailed description of the one or more embodiments of the present disclosure is disclosed hereinafter. It is understood that the one or more disclosed embodiments are merely exemplary of the present disclosure that may be embodied in various and alternative forms. The figures are not necessarily to scale; some features may be exaggerated or minimized to show details of particular components. Therefore, specific structural and function details disclosed herein are not to be interpreted as limiting, but merely as a representative basis for teaching one skilled in the art to variously employ the present disclosure.

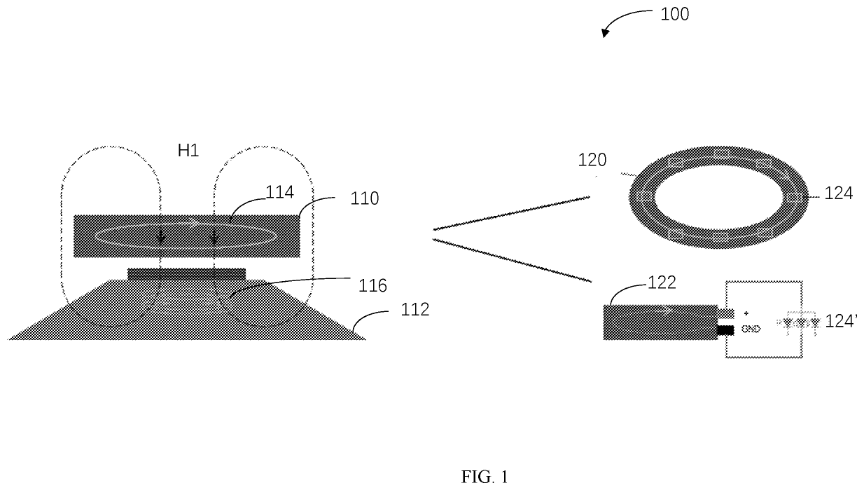

In a headphone, an electrical loop composed of some components on a PCB may be included. Noise may be caused by the electromagnetic influence on the speaker from the electrical loop formed in the headphone. For example, FIG. 1 schematically illustrates a schematic diagram 100 of the noise caused by the electromagnetic influence on the speaker from the loop current flowing in the electrical loop in a headphone. As shown in FIG. 1, the electrical loop 110 is composed of some components on the PCB 120. The electrical loop 110 is located close to the back of the speaker 112 in the headphone. When the loop current 114 goes through the electrical loop, a magnetic field H1 may be generated. The solid arrow indicates the direction of the loop current 114 in FIG. 1, while the dashed arrow indicates the direction of the magnetic field H1. When the loop current 114 varies, the magnetic field H1 may vary, accordingly. According to the Ampere's law, the speaker coil 116 can be moved by the Ampere force from the electrical loop 110. The movement of the speaker coil 116 leads to the vibration of the speaker membrane (not shown) of the speaker, which may generate sound.

The electrical loop 110 may comprise for example a battery 122 and its loads, such as a PCBA with some RGB LEDs 124, as shown in FIG. 1. When the RGB LEDs 124 work, the loop current consumed by these RGB LEDs 124 changes, and the magnetic field H1 may change, accordingly. When the power consumed by these loads changes, the loop current output by the battery 122 changes, and then the magnetic field H1 may vary, accordingly.

Based on the internal arrangement of the headphone as shown in FIG. 1, it can be envisioned that breaking the electrical loop in the PCB layout may decrease the electromagnetic influence in the headphone. This method can be effective for most electrical loops formed in PCBs. However, it cannot be effective for the electrical loop formed by battery and its load in the headphone.

In one way, the electrical loop can be made far away from the speaker to decrease the electromagnetic influence with the increasing of the distance between the electrical loop and the speaker. However, this distance is limited inside the housing of the headphone. Thus, the effectiveness in this way is limited for the headphone.

In another way, arranging the electrical loop plane to be orthogonal to the speaker plane may decrease the electromagnetic influence with the increasing of the angle (0° to 90°) between the electrical loop plane and the speaker plane. However, the angle can also be limited by the casing of the headphone, and the effectiveness in this way is thus limited for the headphone.

In addition, the electromagnetic influence may be decreased with the increasing of the capacity of the capacitor added on the power supply source. The size of the capacitor increases with the increasing of its capacity. The capacitor size however can be limited by the casing. The capacity of the capacitor can also be limited by some SoCs. Alternatively, for the electromagnetic influence caused by the RF transmitting power, such RF transmitting power may be decreased so as to decrease the electromagnetic influence. However, the decreasing of the RF transmitting power may decrease the RF coverage distance. Therefore, the effectiveness of these ways are also limited for the headphone.

Therefore, in order to decrease the electromagnetic influence in the headphone while solving the technical problems addressed above, in one aspect, an apparatus for decreasing the noise caused by the electromagnetic influence in the headphone is provided in the present disclosure.

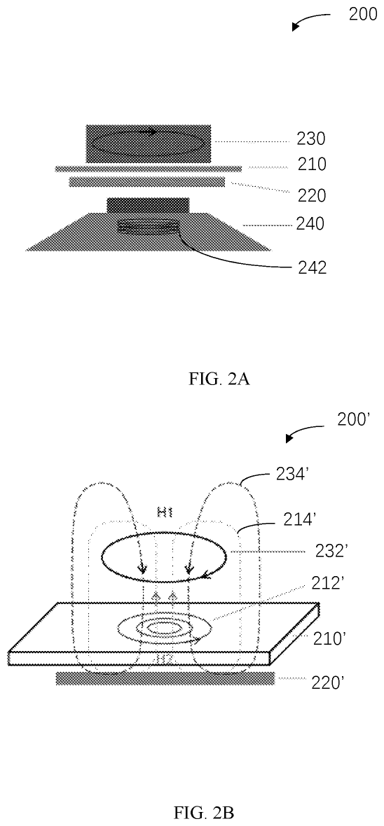

FIG. 2A illustrates an exemplary diagram 200 of the apparatus for decreasing noise caused by the electromagnetic influence in the headphone, according to one or more embodiments of the present disclosure. As shown in FIG. 2A, a metal plate 210 and a magnetic plate 220 have been additionally placed between the electrical loop 230 and the speaker 240 in the headphone. The metal plate 210 can be made of any conductive metal. In an example, the metal plate can be of copper. The metal plate 210, such as copper, is placed between the electrical loop 230 and the magnetic plate 220 inside of the headphone, as shown in FIG. 2A.

FIG. 2B illustrates an exemplary diagram 200′ of decreasing noise caused by the electromagnetic influence in the headphone by mutual cancellation of magnetic fields in the apparatus of FIG. 2A, according to one or more embodiments of the present disclosure. When the loop current 232′ flows in the electrical loop 230, a magnetic field H1 may be generated. In the diagram 200′, the loop current direction in the electrical loop is clockwise (as shown by the solid arrow). According to Ampere's law, the magnetic field line 234′ of the magnetic field H1 passes through the electrical loop 230 from top to bottom (as shown by the dashed arrow). The direction of the magnetic field H1 is counterclockwise. When the loop current in the electrical loop changes, the intensity of the magnetic field H1 changes. According to the eddy current effect, eddy currents 212′ may be generated on the metal plate 210′ by the changing magnetic field H1. Again, according to Lenz's law, the direction of eddy currents 212′ (as shown by the concentric circle arrow) is opposite to the direction of the loop current 232′ in the electrical loop, whereby suppress the variation of the magnetic field H1 which generates the eddy currents 212′. The direction of the eddy currents in the diagram is counterclockwise (as shown by the concentric circle arrow). The eddy currents 212′ generate a magnetic field H2. The direction of the magnetic field H2 is clockwise (as shown by the dot-dashed arrow). The magnetic field line 214′ of the magnetic field H2 passes through the electrical loop from bottom to top (as shown by the dot-dashed arrow). Accordingly, the magnetic field H1 and the magnetic field H2 have opposite directions. Both the magnetic fields H1 and H2 will affect the speaker coil 242 located in the speaker 240. However, the directions of speaker coil movement caused by these two magnetic fields H1 and H2 are different, respectively. The magnetic influences on the speaker from the two magnetic fields H1 and H2 may cancel out with each other. Therefore, the noise caused by these magnetic influences in the headphone can be decreased.

For the metal plate 210′ added in FIG. 2B (also corresponding to 210 in FIG. 2A), the generated eddy currents 212′ in intensity can be associated with the size and thickness of the metal plate 210′. In particular, the eddy currents 212′ increase in intensity with the increasing of the size or thickness of the metal plate 210′. The size and thickness of the metal plate 210′ thus can be tuned according to the noise level tested. In an example, the size and thickness of the metal plate 210′ thus can be tuned according to the tested voltage level of the noise.

Back to FIG. 2A, in the headphone, there is further a magnetic plate 220 placed below the metal plate 210, which may decrease the magnetic fields H1 and H2 crossing the magnetic plate 220. The magnetic plate 220 may be configured to decrease the magnetic influence in the headphone further. As shown in FIG. 2A, the magnetic plate 220 is placed below the metal plate 210, between the electrical loop 230 and the speaker 240, while the metal plate 210 then is located between the electrical loop 230 and the magnetic plate 220. The magnetic plate 220 decreases the magnetic fields H1 and H2 crossing itself. The decreasing of the magnetic fields H1 and H2 may be related to the size and thickness of the magnetic plate 220. The magnetic field crossing the magnetic plate 220 may further decrease as its size or thickness increases.

As noted, the magnetic fields may be decreased by placing a magnetic plate between the electrical loop and the speaker. However, when the distance between the electrical loop and the speaker has to be very short inside the headphone, instead of only adding the magnetic plate therebetween to decrease the magnetic fields crossing the magnetic plate, placing both the metal plate and the magnetic plate between the electrical loop and the speaker in the headphone, as described therebefore, may significantly decrease the electromagnetic interference and greatly save the space required for those components.

In another aspect, in order to decrease the electromagnetic influence in the headphone while solving the earlier mentioned technical problems, a method for decreasing the noise caused by the electromagnetic influence in the headphone is further provided in the present disclosure.

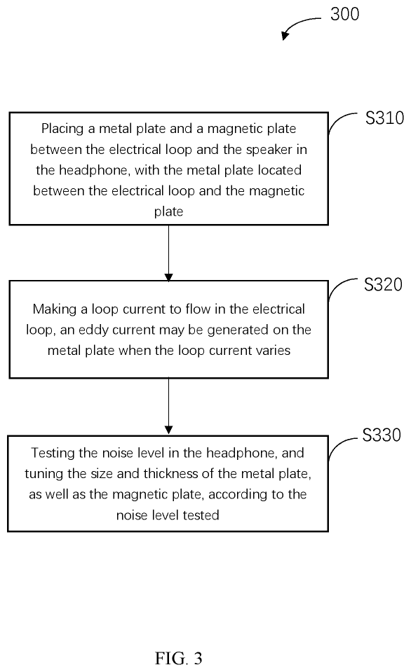

FIG. 3 illustrates an exemplary flowchart 300 of the method for decreasing noise caused by the electromagnetic influence in the headphone, according to one or more embodiments of the present disclosure.

With reference to FIG. 2A, inside the headphone containing the speaker and the electrical loop close to its back, in Step S310, further placing a metal plate and a magnetic plate between the electrical loop and the speaker.

Making a loop current to flow in the electrical loop in Step S320, an eddy current may be generated on the metal plate when the loop current varies. The direction of the eddy current on the metal plate is opposite to that of the loop current in the electrical loop, which may decrease the electrical influence inside of the headphone by way of generating a magnetic field H2 with the eddy current to cancel out the magnetic field H1 brought from the loop current, as described earlier with reference to FIG. 2B.

Next in Step S330, testing the noise level in the headphone, and tuning the size and thickness of the metal plate, as well as that of the magnetic plate, according to the noise level tested.

Compared with other methods, the added metal plate and the magnetic plate may actively decrease the magnetic influence in the headphone. The eddy current varies with the variation of the influencing magnetic field H1. When the magnetic field H1 variation becomes bigger, eddy current variation becomes bigger, accordingly, and then, the magnetic field H2 variation becomes bigger. The increasing magnetic influence on the speaker from the magnetic field H1 and that from the magnetic field H2 still can cancel out with each other.

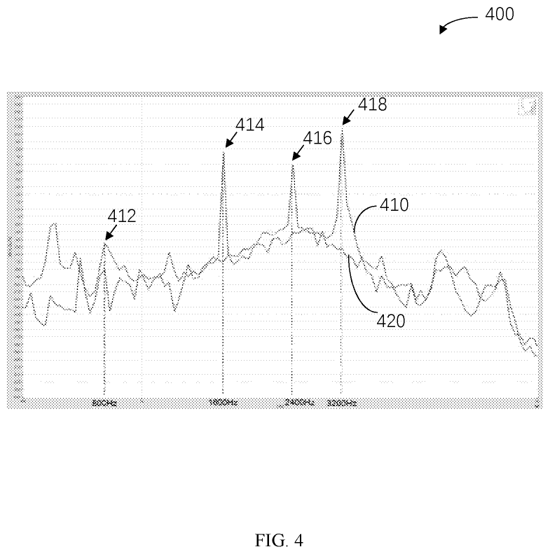

FIG. 4 illustrates a schematic diagram 400 of the background noise test results before and after implementing the method for decreasing noise caused by the electromagnetic influence in the headphone, according to one or more embodiments of the present disclosure. As shown in FIG. 4, the curve 410 represents the frequency spectrogram of background noise in the headphone before applying the metal plate and the magnetic plate to decrease noise caused by the electromagnetic influence. It can be seen that without placing the metal plate and the magnetic plate inside the headphone, there may be some peaks existing on the curve 410, such as at the frequencies of 800 Hz, 1.6 kHz, 2.4 kHz, and 3.2 kHz, denoted by numeral references 412, 414, 416 and 418, respectively. These peaks are caused by the electromagnetic influence from the battery. They are audible noise which can be heard.

In contrast, the curve 420 represents the frequency spectrogram of the background noise tested in the headphone after applying the metal plate and the magnetic plate provided in the method according to the present disclosure, which are placed between the electric loop and the speaker in the headphone. Those previously mentioned peaks all disappear, and almost no such noise can be heard inside the headphone.

The apparatus and method provided herein may effectively decrease the noise caused by the magnetic influence in the headphone. By implementing this method, several benefits may be achieved such as described below. The electromagnetic influence on the speaker may be significantly decreased. Compared to prior methods, the electromagnetic influence may be actively decreased. The space requirements for the headphone housing may be much smaller than that by other methods. The mechanical design remains unchanged. Neither decreasing of RF transmitting power nor impact on the RF distance is necessary. Large capacitors are not required in the battery on the PCB inside the headphone.

In the foregoing description, the present disclosure has been described with reference to one or more embodiments thereof. It will, however, be evident that various modifications and changes may be made thereto without departing from the broader scope of the present disclosure. For example, the above-described process flows are described with reference to a particular ordering of process actions. However, the ordering of many of the described process actions may be changed without affecting the scope or operation of the present disclosure. The description and drawings are, accordingly, to be regarded in an illustrative rather than restrictive sense.

As used in the disclosure, an element or step listed in the singular form and preceded by the word “one/a” should be understood as not excluding a plurality of said elements or steps, unless such exception is specifically stated. Furthermore, references to “embodiments” or “examples” of the disclosure are not intended to be construed as exclusive, also including the existence of other embodiments of the recited features. The terms “first”, “second”, “third”, etc. are used only for identification and are not intended to emphasize a numerical requirement or positioning order of their objects.

References in the present disclosure to the apparatus for decreasing noise caused by electromagnetic influence in the headphone and the method thereof include the following content:

Item 1: In one or more embodiments, the present disclosure provides an apparatus for decreasing noise caused by electromagnetic influence in a headphone, comprising: a speaker with a speaker coil and a speaker membrane and an electrical loop with a loop current flowing therein, arranged close to the back of the speaker. The apparatus further comprises a metal plate and a magnetic plate both placed between the electrical loop and the speaker, with the metal plate located between the electrical loop and the magnetic plate and an eddy current may be generated when the loop current varies in the electrical loop, and the direction of the eddy current is opposite to that of the loop current.

Item 2: The apparatus of item 1, wherein a size and thickness of the metal plate is tuned according to a tested voltage level representative of noise.

Item 3: The apparatus of item 1 or 2, wherein a first magnetic field (H1) may be generated when the loop current flows in the electrical loop.

Item 4: The apparatus of any of items 1-3, wherein the noise may be generated by a vibration of the speaker membrane led by a movement of the speaker coil due to an Ampere force caused by variations in the first magnetic field (H1).

Item 5: The apparatus of any of items 1-4, wherein a direction of a second magnetic field (H2) is generated by eddy current variation opposite to that of the first magnetic field (H1).

Item 6: The apparatus of any of items 1-5, wherein a magnetic influence on the speaker from the first magnetic field (H1) and that from the second magnetic field (H2) may cancel out with each other.

Item 7: The apparatus of any of items 1-6, wherein the metal plate may be of any conductive metal, wherein the metal plate may be of copper.

Item 8: The apparatus of any of items 1-7, wherein the magnetic plate may be configured to decrease the first and the second magnetic fields (H1, H2) crossing the magnetic plate.

Item 9: The apparatus of any of items 1-8, wherein the decreasing of the first and the second magnetic fields (H1, H2) crossing the magnetic plate may be associated with the size and thickness of the magnetic plate.

Item 10: The apparatus of any of items 1-9, wherein the first and second magnetic fields (H1, H2) crossing the magnetic plate may be decreased more with the increasing of the size or thickness of the magnetic plate.

Item 11: In one or more embodiments, the present disclosure provides a method for decreasing noise caused by electromagnetic influence in a headphone, comprising the steps of: placing a metal plate and a magnetic plate between an electrical loop and a speaker in the headphone, with the metal plate located between the electrical loop and the magnetic plate and making a loop current to flow in the electrical loop. An eddy current may be generated on the metal plate when the loop current varies in the electrical loop, and the direction of the eddy current is opposite to that of the loop current.

Item 12: The method of item 11, further comprising the step of testing a voltage level of the noise and tuning a size and thickness of the metal plate according to the tested voltage level representative of noise.

Item 13: The method of item 11 or 12, wherein a first magnetic field (H1) may be generated when the loop current flows in the electrical loop.

Item 14: The method of any of items 11-13, wherein the noise may be generated by a vibration of the speaker membrane led by a movement of the speaker coil due to an Ampere force caused by variations in the first magnetic field (H1).

Item 15: The method of any of items 11-14, wherein a direction of a second magnetic field (H2) generated by eddy current variation opposite to that of the first magnetic field (H1).

Item 16: The method of any of items 11-15, wherein a magnetic influence on the speaker from the first magnetic field (H1) and that from the second magnetic field (H2) may cancel out with each other.

Item 17: The method of any of items 11-16, wherein the metal plate may be of any conductive metal, wherein the metal plate may be of copper.

Item 18: The method of any of items 11-17, wherein the magnetic plate may be configured to decrease the first and second magnetic fields (H1, H2) crossing the magnetic plate.

Item 19: The method of any of items 11-18, wherein the decreasing of the first and the second magnetic fields (H1, H2) crossing the magnetic plate may be associated with the size and thickness of the magnetic plate.

Item 20: The method of any of items 11-19, wherein the first and the second magnetic fields (H1, H2) crossing the magnetic plate may be decreased by increasing the size or thickness of the magnetic plate.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. An apparatus for decreasing noise caused by electromagnetic influence in a headphone, the apparatus comprising:
a speaker including a speaker coil and a speaker membrane; and
an electrical loop having a loop current flowing therein, arranged close to a back of the speaker;
wherein the apparatus further comprises a metal plate and a magnetic plate both placed between the electrical loop and the speaker, with the metal plate located between the electrical loop and the magnetic plate, and
wherein an eddy current is generated when the loop current varies in the electrical loop, and a direction of the eddy current is opposite to that of the loop current.

2. The apparatus of claim 1, wherein a size of the metal plate is tuned according to a tested voltage level representative of noise.

3. The apparatus of claim 1, wherein a first magnetic field (H1) is generated when the loop current flows in the electrical loop.

4. The apparatus of claim 3, wherein the noise is generated by a vibration of the speaker membrane led by a movement of the speaker coil due to an Ampere force caused by variations in the first magnetic field (H1).

5. The apparatus of claim 3, wherein a direction of a second magnetic field (H2) is generated by eddy current variation opposite to that of the first magnetic field (H1).

6. The apparatus of claim 5, wherein a magnetic influence on the speaker from the first magnetic field (H1) and that from the second magnetic field (H2) may cancel out with each other.

7. The apparatus of claim 1, wherein the metal plate includes a conductive metal.

8. The apparatus of claim 5, wherein the magnetic plate is configured to decrease the first and the second magnetic fields (H1, H2) crossing the magnetic plate.

9. The apparatus of claim 8, wherein the decreasing of the first and the second magnetic fields (H1, H2) crossing the magnetic plate is based on a size of the magnetic plate.

10. The apparatus of claim 8, wherein the first and second magnetic fields (H1, H2) crossing the magnetic plate decreases more with increasing of a size of the magnetic plate.

11. A method for decreasing noise caused by electromagnetic influence in a headphone, comprising the steps of:
placing a metal plate and a magnetic plate between an electrical loop and a speaker in the headphone, with the metal plate located between the electrical loop and the magnetic plate; and
generating a loop current to flow in the electrical loop,
wherein an eddy current is generated on the metal plate when the loop current varies in the electrical loop, and a direction of the eddy current is opposite to that of the loop current.

12. The method of claim 11, further comprising the step of testing a voltage level of the noise and tuning a size of the metal plate according to the tested voltage level representative of noise.

13. The method of claim 11, wherein a first magnetic field (H1) may be generated when the loop current flows in the electrical loop.

14. The method of claim 13, wherein the noise is generated by a vibration of a speaker membrane led by a movement of a speaker coil due to an Ampere force caused by variations in the first magnetic field (H1).

15. The method of claim 13, wherein a direction of a second magnetic field (H2) is generated by eddy current variation opposite to that of the first magnetic field (H1).

16. The method of claim 15, wherein a magnetic influence on the speaker from the first magnetic field (H1) and that from the second magnetic field (H2) may cancel out with each other.

17. The method of claim 11, wherein the metal plate is made of a conductive metal.

18. The method of claim 15, wherein the magnetic plate is configured to decrease the first and second magnetic fields (H1, H2) crossing the magnetic plate.

19. The method of claim 18, wherein the decreasing of the first and the second magnetic fields (H1, H2) crossing the magnetic plate is based on a size of the magnetic plate.

20. The method of claim 18, wherein the first and the second magnetic fields (H1, H2) crossing the magnetic plate decreases by increasing a size of the magnetic plate.
